(19) United States
(12) Patent Application Publication
(10) Pub. No.: US 2008/0006922 A1
(43) Pub. Date: Jan. 10, 2008

(54) Thermal release adhesive-backed carrier tapes

(76) Inventor: Charles Gutentag, Los Angeles, CA (US)

Correspondence Address: ROZSA LAW GROUP LC, 18757 BURBANK BOULEVARD, SUITE 220, TARZANA, CA, 91356-3346, US

(21) Appl. No.: 11/482,657

(22) Filed: Jul. 8, 2006

(51) Int. Cl. H01L 23/02

(52) U.S. Cl. 257/686

(57) ABSTRACT

The specification describes methods for releasing adhered components to adhesive-backed carrier tapes. It is based on the recognition that with proper choice of the adhesive, i.e. a thermal release adhesive, selectively applied heat will modify the adhesive, eliminating or substantially reducing the adhesion between the tape and the IC chip. This allows components to be picked from the adhesive-backed carrier tape without mechanical assistance. Thermal release adhesives having fast rise times are preferred, allowing for pick and place cycles of less than one second, e.g., less than 0.5 seconds. Preferred means for applying selective heat to the adhesive on the carrier tape are ceramic heaters. Other choices are arc lamps, tungsten halogen lamps, xenon lamps, lasers, and infra-red lamps.

### FIELD OF THE INVENTION

The field of the invention is storage and transport carrier tape systems for small electronic components. More specifically, it is directed to methods and apparatus for handling small electronic components using thermal release adhesive-backed carrier tapes.

### BACKGROUND OF THE INVENTION

As the size of small electronic parts shrinks, methods for packing these components for automated handling become more challenging. Automated factories cannot function efficiently unless the feedstock components are pre-packed in a uniform, industry standard manner. In integrated circuit (IC) device manufacture, the individual IC chip size may be less than one millimeter per side. The operative phrase “Die Shrink” is a principle objective of silicon wafer fabricators for two primary reasons: (1) the continuing demand for smaller, lighter, consumer electronic devices with additional performance features (led by mobile telephones) which require more functions within smaller form factors; (2) achieve added cost reductions by increasing chip quantities and yields obtained from each wafer produced.

Components packed in a tape and reel format for low cost, high volume, pick and place assembly in automated factories are widely used in the electronics industry. These carrier tapes and their use may be found in co-pending application Ser. No. 11/198,669, filed Aug. 5, 2005, which is incorporated by reference herein.

The following description is largely in terms of IC chips as the components being transported by the carrier tape. It should be understood that IC chips are but one type of component stored and transported using carrier tapes and carrier tape conveyor systems of the kind described here. Discrete components, e.g. resistors, capacitors, inductors, and combinations thereof, and photonic devices such as optical integrated circuits, photodiodes, laser chips, micro-machined devices (MEMS), micro-mirrors, etc., are also processed and assembled using carrier tape transport and storage. The term component is intended to be generic to any of these assemblies and devices.

Pick and place operations for IC chips typically involve picking individual IC chips at the dicing station, placing the IC chips individually in designated sites on the carrier tape, moving the carrier tape to another pick station, picking the IC chips from the carrier tape, and placing the IC chips on a support substrate, for example a printed circuit board. Pick and place operations in a surface mount technology (SMT) assembly involve picking packaged SMT components at a packing station, placing the SMT components on a carrier tape, conveying the carrier tape to an assembly station, picking the SMT components from the carrier tape, and placing the SMT components on an assembly board such as a printed wiring board, or a silicon interconnection substrate. Precision pick and place for IC chips is obviously the most challenging due to the small size of the IC chips and the typically demanding tolerances for IC chip placement. Accordingly, pick and place operations, and carrier tape conveying systems, as applied to semiconductor IC chips and correspondingly small photonic devices, are the main objectives of the invention.

Carrier tapes are used in several forms. A widely used carrier tape has individual pockets or cavities for containing the components, e.g. IC chips. After silicon IC wafers are diced, a pick and place machine picks chips individually and places them in the carrier tape pockets. The carrier tapes may be reeled for storage, or for transport to the next processing station. The tapes are unreeled at the next processing station and the chips are individually picked and placed again. Since the IC chips (or other components) are confined loosely in the carrier tape pockets, a cover tape is used to enclose the pockets. The cover tape is applied after the pockets are filled, and later peeled back to allow the next pick and place operation.

Historically, IC wafer die have been bonded to a leadframe and encapsulated. These so-called “packaged IC's” generally conform to a finite number of Industry Standards and Registered Outlines and are conveniently packed in matrix trays and in embossed, carrier tape (so-called “pocket tape”) for automated handling. Typically, these Packaged IC's are one or more orders of magnitude larger and heavier than the IC chips, which they contain. Singulated IC wafer die, best known as Die Products, can be FUNCTIONAL counterparts of Packaged IC's. However the vast PHYSICAL differences between Die Products and Packaged IC's requires new designs for packing materials to achieve high speed, low cost automated handling to maximize both throughput and yields. The advent of Chip Sized Packaging (CSP) allows for the packaged component to be similar in size and weight to the Die Product that it contains, making them equally difficult to handle as bare die. Component carrier tapes are used in several forms. The aforementioned Embossed Carrier Tape (Pocket Tape) has individual pockets or cavities sized and shaped to conform to the outline dimensions of the components. However, there are numerous drawbacks to use of conventional embossed pocket tape and punched cavity tape for handling bare die.
1) Absent Industry Standards for bare die products, these devices are produced in virtually any combination of cut size dimensions consistent with form factor requirements and maximum yields per wafer. Because the cavity size must closely approximate the size of the chip placed therein while allowing ease of chip ingress/egress without restriction, chips are free to move laterally in X-Y- and theta and vertically in angular tilt, resulting in potential damage to die during transit and difficulty in locating and picking extremely small die for retrieval by conventional pick tools.
2) Conventional punched and embossed carrier tapes are not suitable for use with micro-sized bare die, which are virtually weightless devices. These carrier tapes require peel-back removal of a top cover tape to gain access to each die product for pick and place assembly. Variations in peel force will dislodge micro-size chips and cause them to stand on end (called “tombstoning”) or flip out of the tape cavities before pick. Triboelectric charges developed during the peel-back removal will cause micro-size chips to cling to the cover tape. The extremely low mass of microchips allows them to literally “float” like particles of dust, ignoring the Laws of Gravity.
3) The multiplicity of bare die sizes creates a logistics problem for maintaining proper inventories of carrier tapes with fixed cavities, sized to the dimensions of each individual die. This problem is further intensified by the inevitable consequences of die shrink.
4) Bare die products are frequently singulated from silicon wafers, which have been “thinned” to dimensions as small as 25 microns. Because cover tapes are not sealed between adjacent cavities, thin die can move beneath the cover tape to adjacent cavities (known as “shingling”). Such movement prevents retrieval of individual die from cavities and result in multiple die damage.

A type of carrier tape that at least in part overcomes the disadvantages of embossed pocket tape and punched cavity tape is adhesive-backed carrier tape. With this type of carrier tape, the chips are retained within virtual boundary compartments, and held therein, exactly as placed, by a pressure-sensitive adhesive tape. The adhesive tape is affixed to the backside of the carrier tape plastic frame. An important advantage of the adhesive-backed carrier tape is that repeatable positioning of the components at the pick point can be achieved with high precision, e.g. within 10 microns. Because each chip is retained by the adhesive in the exact position as placed, when a given compartment reaches the pick station, the pick tool knows precisely where the chip is and how the chip is oriented. This allows the pick to be made “blind”, and eliminates the need for expensive tools to “find” the IC chips on the carrier tape. Methods and apparatus for implementing this are described and claimed in my co-pending patent application (Gutentag Case 3) filed Jun. 20, 2006. The methods and apparatus described in this application are based partly on a new design philosophy wherein high precision is added to the carrier tape and carrier tape conveying apparatus, rather than just the pick and place apparatus.

A carrier tape conveyor apparatus using adhesive-backed carrier tape is typically provided with mechanical means for aiding in releasing the chip from the adhesive on the carrier tape. The mechanical means may be an ejector pin or rod that bears on the bottom of the chip and, while the pick head is engaging the chip, urges the chip away from the tape. To accommodate the ejector pin the adhesive-backed carrier tape is formed as two rails with a continuous opening traversing the center of the tape. While this carrier tape, and this carrier tape conveying system design is effective, and has been successful in practice, improvements are sought.

### STATEMENT OF THE INVENTION

I have discovered a new mechanism for releasing adhered components to adhesive-backed carrier tapes. It is based on the recognition that with proper choice of the adhesive, i.e. a thermal release adhesive, selectively applied heat will modify the adhesive to eliminate or substantially reduce the component-to-tape peel adhesion. This allows components to be picked from the adhesive-backed carrier tape by action of the pick tool alone, i.e. without mechanical assistance. Thermal release adhesives with fast rise times are preferred, allowing for pick and place cycles of less than one second, e.g., less than 0.5 seconds, and potentially less than 100 milliseconds. Preferred means for applying selective heat in the range of 100 to 120 degrees C. are ceramic heaters. Other choices are arc lamps, tungsten halogen lamps, xenon lamps, lasers, and infrared lamps. Such means of heating could be incorporated in conventional motor driven feeders for punched carrier tape.

### BRIEF DESCRIPTION OF THE DRAWING

The invention may be better understood when considered in conjunction with the drawing in which:

FIG. 1 is a schematic diagram of a punched, adhesive-backed, carrier tape;

FIG. 2 is a section view through 2-2 of FIG. 1;

FIG. 3 is a side view of the adhesive-backed carrier tape shown in FIG. 2;

FIG. 4 is a schematic view of a conventional adhesive-backed carrier tape and carrier tape conveyor system;

FIG. 5 is a schematic view of an adhesive-backed carrier tape and carrier tape conveyor system modified according to the teachings of the invention;

FIGS. 6 and 7 are views similar to FIGS. 1 and 3 illustrating a modification in the design of the adhesive-backed carrier tape to implement the invention;

FIG. 8 is a diagram of a thermal release adhesive tape useful for the invention; and

FIG. 9 is a plot of temperature vs. adhesion for a thermal release adhesive tape.

### DETAILED DESCRIPTION OF THE INVENTION

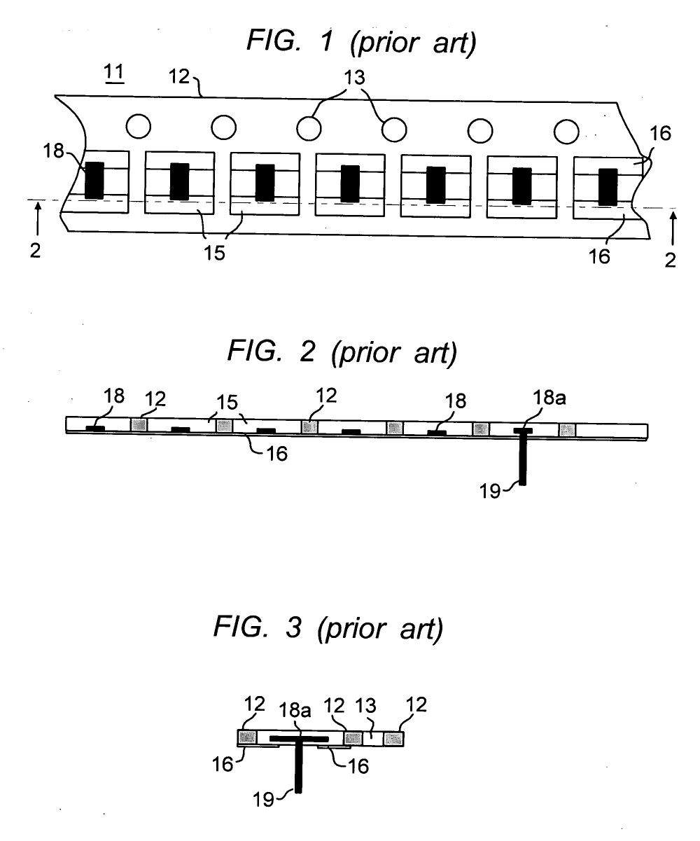

With reference to FIG. 1, an adhesive-backed carrier tape is shown generally at 11, comprising a continuous length of flexible punched plastic carrier tape 12, sprocket holes 13 for driving and positioning the tape, carrier tape compartments 15, and the pressure-sensitive adhesive backing tape 16. In this illustration the carrier tape compartments are shown loaded with IC chips 18. As indicated above, IC chips 18 are illustrative only of the kinds of parts and components that can be processed using the carrier tape conveyor system of the invention. The pressure sensitive adhesive tape 16 itself is a relatively thin (e.g. 75 micron) continuous tape that is adhesively affixed to the punched plastic carrier tape frame 12.

The adhesive-backed carrier tape is shown in cross section in FIG. 2. The carrier tape 12 has a front side (top) and a back side (bottom), with chip site openings extending through the chip carrier tape. The chip site openings have an adhesive backing 16 extending along the back side of the chip carrier tape, thus forming a plurality of compartments 15 for housing components 18.

The view is taken through the compartments 15 so only the portions 12 of the carrier tape, the portions separating the compartments, appears. The tape 12 is relatively thick, typically 0.1 to 1.0 mm, to provide a standoff for the compartments. The standoff is typically greater than the thickness of the components stored in the tape compartments so that the components are not touched and disturbed when the tape is reeled. The adhesive backing is shown at 16. As seen in FIG. 1, the adhesive backing is split into two rails. This allows the amount of adhesion between the carrier tape and the chips 18 to be varied depending upon the width of the adhesive tape rails 16. It also allows a pin to be inserted through the bottom of the carrier tape, to engage the chip 18 and aid in releasing the chip from the adhesive backing. These features are generally known and described for example in U.S. Pat. No. 5,203,143, which patent is incorporated herein by reference.

As just mentioned carrier tape conveyor systems for adhesive backed carrier tapes are usually provided with an ejector pin. This is schematically illustrated in FIG. 2 where ejector pin 19 is one embodiment of a release device to aid in removing chip 18a from the adhesive backing of the carrier tape. The is ejector pin operates in cooperation with the pick head (not shown in this figure). One reason for the split rail design for the adhesive tape, shown in FIG. 1, is evident here. Other types or forms of ejector mechanisms may be used. Typically, such an ejector mechanism will not be found associated with pocket tape conveyors since components that are conveyed as floating objects in the carrier tape pockets are easily lifted from the tape by a vacuum pick tool.

The adhesive-backed carrier tape shown along its length in FIG. 2 is shown across the width in FIG. 3. Noteworthy here is the view of the split rail backing tape 16. As just mentioned, the split rail design is used to accommodate the ejector pin 19. It may also be used to adjust the adhesion between the adhesive-backed carrier tape and the IC chip 18a. The separation between the rails may be increased or decreased to increase or decrease the adhesive surface area that contacts the IC chip. This in turn increases or decreases the effective adhesion between the IC chip and the carrier tape. Similar results may be achieved by modifying the edge design of the adhesive backing tape. For example, a serrated edge will provide a different area for adhesive attachment than a straight edge. Other mechanisms for adjusting the adhesion between the IC chip and the carrier tape are described in co-pending application Ser. No. 11/198,669, filed Aug. 5, 2005, which application is also incorporated by reference herein.

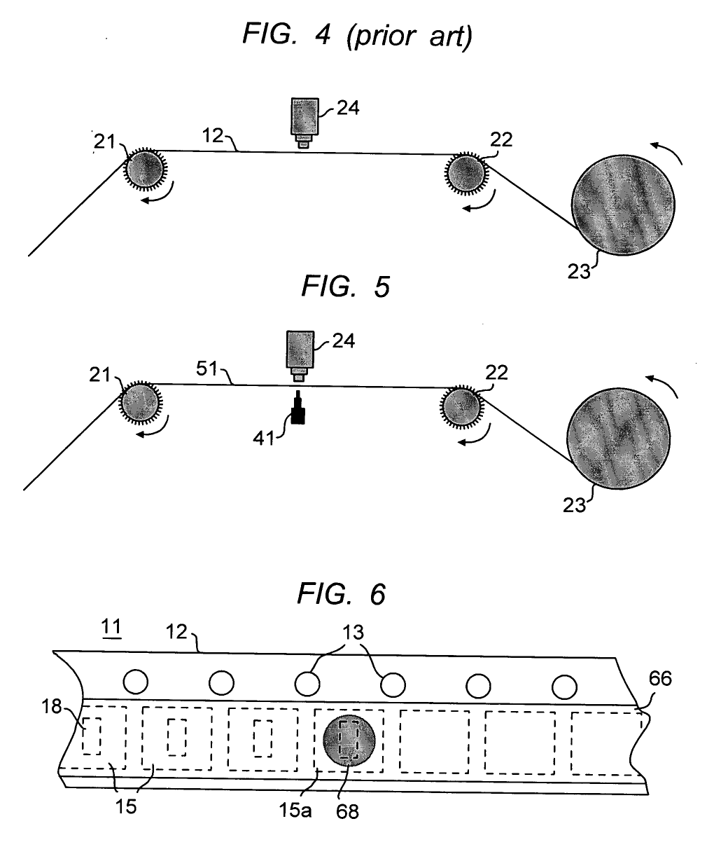

A typical conveying apparatus for adhesive-backed carrier tape is shown in FIG. 4. The illustration is for a component placement operation wherein the adhesive-backed carrier tape 12 is unreeled from a tape reel to the left of the figure (not shown), passed beneath a component placement head 24, and reeled onto tape reel 23. The objective is to place each IC chip in a precise, predetermined position on the carrier tape. Since the chip remains in place during transport, due to the adhesive tape backing, the position of the chip will be known when the carrier tape reaches the next pick station.

The apparatus in FIG. 4 is shown very schematically to indicate that a variety of mechanical implementations are possible for moving the carrier tape underneath the chip placement head. The details of the placement head are also not part of the invention. Pick heads and placement heads in pick and place tools are well known, and typically operate pneumatically to dispense chips individually onto the tape for the place operation, and to vacuum the chips individually from the tape on the pick operation. The drive wheels are shown at 21 and 22, and are sprocket wheels of general design. Wheels 21, 22, and 23 are coordinated for advancing the tape under the placement head 24. In some cases in the prior art, a single drive wheel may be used, with other guiding wheels provided as follower wheels. However a preferred arrangement is to provide at least one drive wheel along the tape path on each side of the placement head 24. These wheels may be electromechanically coupled to allow the tape to be controllably driven in both the forward and the reverse directions. Moreover, two or more positive drive wheels help to stabilize the movement and position of the tape.

In typical carrier tape conveyor systems the carrier tape is advanced in steps, where the step distance corresponds to the pitch of the compartments in the tape. The compartment pitch on typical carrier tapes is in whole number multiples of 4 mm with ½ and ¼ pitches (2 mm and 1 mm) used for extremely small components. The tape is stepped so that each compartment sequentially reaches a process station for a process operation, for example a place operation or a pick operation. The usual objective is to perform these operations as quickly as practical, meaning that the tape is advanced rapidly to achieve that goal. State-of-the-art pick and place machines operate at 1-10 operations per second. This means that the cycle time per operation may be as rapid as 100 ms.

According to the invention, the pick operation is implemented using a new mechanism for effecting the removal of the IC chips from the adhesive layer on the adhesive-backed carrier strip. The conventional adhesive tape used in the carrier tape is replaced with a thermal release adhesive tape. When the IC chip being picked reaches the site of the pick head, the heat release tape is locally heated, reducing the adhesion of the adhesive tape at the pick site to essentially zero, or near zero. This allows the vacuum pick head to remove the IC chip from the adhesive-backed carrier tape without the need for mechanical assistance, i.e. without using an ejector pin. FIG. 5 illustrates the modified carrier tape conveyor system wherein the tape 12 in the prior art system is replaced by a thermal release carrier tape 51, and subassembly 41 is provided for heating the thermal release tape at a position essentially coincident with the pick head 24.

A variety of heat sources may be used as subassembly 41 for locally heating the thermal release tape, for example, ceramic heating elements, lasers, resistance heating elements, including, arc lamps, UV lamps, infra red lamps, xenon lamps, induction heaters, etc. The primary requirement for effecting release is to raise the temperature of the adhesive material on the thermal release tape. The mechanism for doing this may involve heating the adhesive, heating the tape, or heating both the tape and the adhesive material. Thermal release adhesives are described in Japanese patent applications 3-228861 and 5-226527. A thermal release tape is available as REVALPHA, manufactured by Nitto Denko. This tape is normally provided with a release liner, but the liner may be omitted to expose the adhesive layer for the applications described here.

FIG. 6 shows a circle of heat, represented by region 68, applied locally and selectively to the adhesive tape 66 in compartment 15a. The heat may be applied using several heating approaches. Radiant heat from a radiant heat source may be used with a suitable aperture to localize the heat to the ring represented by 68 in FIG. 6. A light source, such as a laser, or other heat lamp, is a convenient method since the heat can be locally applied by properly focusing the light beam on the spot 68 in FIG. 6.

Especially suitable heat sources are ceramic heaters supplied by Watlow Co., St. Louis, Mo. Details on these heating elements, and design rules for their implementation in applications such as the one described here, are available through www.watlow.com., the content of which is incorporated by reference herein. These heaters are designed to produce fast rise times. Fast rise times are necessary if the tape conveyor system is operated at high speeds. Heat from the heating element can be applied to the tape using various approaches. The heating element may be mounted just below the path of the tape, as shown at 41 in FIG. 5. In this approach, at least two options are available. The heating element may be activated and remain on, while the tape is conveyed past the heating element and the pick head. Using simple empirical methods, the temperature and proximity of the heating element is correlated with the tape speed so that the thermal release tape at the pick location reaches the required release temperature. These parameters will vary depending on the specific characteristics of the conveyor system and the thermal release tape.

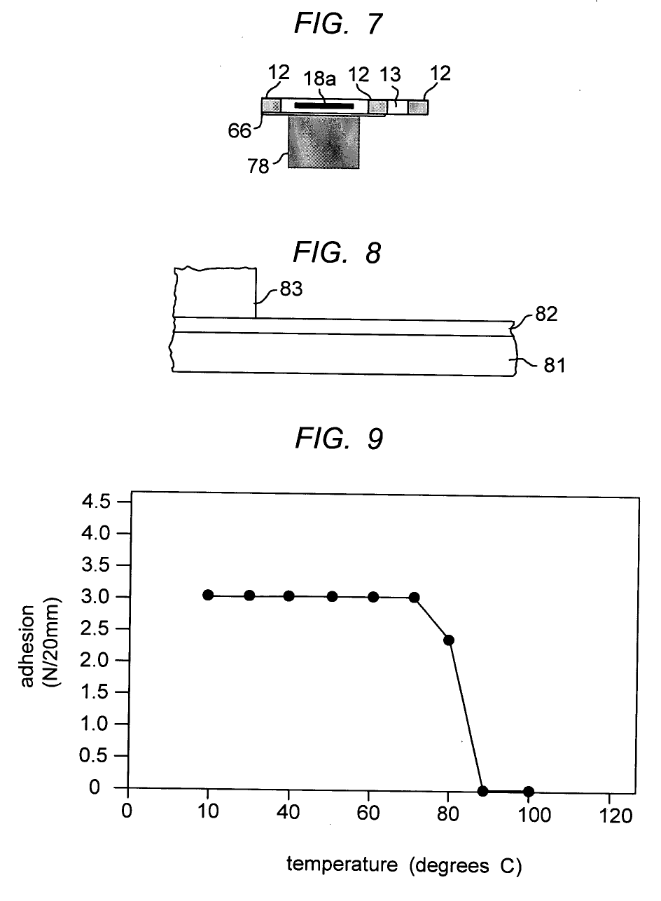

Another option is to move a heated element into contact with the thermal release tape. This approach is suggested in FIG. 7, where the heated element 78 is shown raised into contact with the thermal release tape 66. The heated element 78, sometimes referred to as an anvil, may be raised and lowered in cooperation with the pick head and the tape speed. This approach has been successfully demonstrated in practice, whereby the thermal release tape has been locally heated to 120 degrees C. for 50-100 milliseconds, thereby reducing the adhesion of the thermal release tape to essentially zero, and allowing the pick head to remove the IC chip 18a from the adhesive-backed carrier tape 66. This heating technique is consistent with commercially used carrier tape speeds.

In yet another alternative embodiment of the invention, the heat source may be selected to primarily heat the IC chip, and secondarily the adhesive material on the adhesive tape. This adds another option, using induction heating of the IC chip. An alternative choice for the heat source, with the focus on rapidly heating the IC chip, is an arc lamp. The radiation from arc lamps may be tailored to the absorption characteristics of the IC chip so that very fast rise times are produced. Other options include tungsten-halogen lamps, which produce state-of-the-art heating cooling cycles. An advantage of this approach is that the heating area is self-focused to the portion of the thermal release tape where heating is required in order to release the IC chip. Only the portion of the thermal release tape that contacts the IC chip is heated. This means, inter alia, that the beam can flood the tape or the tape compartment. The areas of the thermal release tape that are devoid of surface contact with the chip and the adhesion of the thermal release carrier tape in those areas will remain unaffected.

A preferred method used for attaching the thermal release tape to-the carrier tape is to use the adhesion inherent in the thermal release tape. Care should be exercised to prevent excessive delamination of the thermal release tape from the carrier tape. Some delamination may be tolerated. However, it is preferred that the heat from the heat source be largely localized to the compartments of the carrier tape, and not excessively heat the carrier tape itself. FIGS. 6 and 7 show the heat applied to the thermal release tape only at the location of the pick head. For effective results it is only required that the thermal release tape reach the final release temperature coincident with the pick head moving to pick the IC chip. However heating may commence at an earlier point. This allows the effective heating area to overlap more than one compartment. A consequence of this approach is that heat may be applied to those portions 12 of the carrier tape shown in the section view of FIG. 2. In cases where this option proves useful, the slight delamination of the thermal release tape on the ribs separating the compartments may be acceptable, since the thermal release tape will still be firmly attached to the carrier tape along each edge. This option allows the speed of the carrier tape to be increased, since all of the thermal rise time required to release the IC chip from the thermal release tape does not have to occur during a single step in the tape advance.

A representative view of the carrier tape with a thermal release tape is shown in FIG. 8, where the thermal release carrier tape backing is shown at 81 and thermal release adhesive layer is shown at 82. An edge of the carrier tape itself (12 in FIG. 1) is shown at 83.

A plot of adhesion vs. temperature for a typical thermal release tape is shown in FIG. 9. The adhesion drops sharply as the temperature of the adhesive layer 82 increases from approximately 50 degrees C. to approximately 90 degrees C. This plot supports the description above, where the temperature of the thermal release tape may rise due to heat applied prior to reaching the actual site of the pick operation. During a substantial part of the thermal rise time the adhesion of the thermal release tape is still sufficient to maintain the desired position of the IC chip. The actual rise time may be 50-100 ms. For most applications of the type contemplated here, the thermal rise time from room temperature (approximately 20 degrees C.) to 120 degrees C. should be less than 1 second and preferably less than 500 ms. Premium machines for very high speed processing lines may require rise times of less than 100 ms, or even less than 50 ms.

From the data shown in FIG. 9 it is evident that the thermal release mechanism proceeds rapidly to essentially zero. From the discussion above, it should be evident that one goal of the invention is to reduce the adhesion to a low value, a value that allows the vacuum pick head to remove a component from the adhesive-backed carrier taper without mechanical assistance. Clearly an adhesion value of zero allows that result. However, low adhesion values above zero may also allow that result, for example, less than 0.5 N/20 mm. In a functional sense, an adhesion value of “essentially zero” should be construed as including these low values.

It is also evident from this discussion that the thermal release adhesive tape have sufficient adhesion to hold the components in place while conveying them from one station to another, or reeling them for storage and transport. The actual adhesion levels desired may vary depending on the application, the size and shape of the components, etc., but, in general, values above 1.0 N/20 mm would most likely be suitable for many applications. This suggests that the change in adhesion due to applied heat would be of the order of at least 0.5 N/20 mm. More typically, the change will be greater than 1.5 N/20 mm. Recalling that in the preferred case, the adhesive backing tape is attached to the carrier tape by the thermal release adhesive, the adhesion should be relatively robust. However, in cases where lower initial levels of adhesion are found suitable for the thermal release mechanism, another adhesive, or additional adhesive, may be used to laminate the thermal release adhesive tape to the carrier tape.

In the embodiments shown in FIGS. 6 and 7 there is a single component loaded in each compartment. An advantage of using the adhesive-backed carrier tape of the invention is that two or more components (referred to here as multiple components) may be loaded into a single compartment. This expedient may be especially useful where components are paired, or used in MCMs. Multiple components may be placed in a single compartment where the components are the same, or different. “The same, or different” is meant to refer to the electrical function of the component, for example two transistors or two diodes would be components of the same type. A transistor and a diode, would be components of different types. Where the components are of the same type, they may comprise a matched pair of, for example, matched transistors or matched diodes that have been selected at the wafer level, and identified as a matched set. The pick tool can identify each of the components by the position in the compartment where each component is found. Matched pairs, or matched multiple components, of different types may also be identified as a compatible group. For example, an LC pair may be tested as a pair at the wafer level, and loaded as a pair in a single compartment. When the components are different, loading into a single compartment is allowed because the components remain in the precise relative position where they are placed, and the sequence of loading and unloading (placing and picking) allows the individual components to be easily recognized. The multiple components may be placed in a serial sequence, or may be placed, for example, on four corners of a quadrilateral in a single compartment. The multiple components may be placed and picked serially in individual place and pick operations, or may be placed and picked as a group. Simple modification of the pick and place tool heads will allow components to be placed and picked in groups. Again, this expedient is made practical because the position of each component as placed is retained precisely during storage and transfer. To effect the thermal release of multiple components for a multiple component pick, heat to release the components is applied simultaneously to all of the multiple components being picked. When multiple components are carried in a single compartment, and are serially picked by the pick tool, either the tape can be advanced a suitable fraction of the pitch of the compartments for each individual pick, or the pick head can be repositioned to pick each individual component. Movement of the pick head would normally be along the length of the tape, but could be transverse to the tape advance direction to pick multiple components placed on the corners of a quadrilateral. It is also possible to use an adhesive-backed carrier tape that has no individual compartments. In this case at least some of the ribs between compartments could be eliminated and the edge rails would be the main elements used for handling and advancing the tape.

Various additional modifications of this invention will occur to those skilled in the art. All deviations from the specific teachings of this specification that basically rely on the principles and their equivalents through which the art has been advanced are properly considered within the scope of the invention as described and claimed.

1. A method for conveying components on an adhesive-backed carrier tape wherein the adhesive-backed carrier tape comprises a thermal release adhesive material comprising:
a. placing a component on the thermal release adhesive material,
b. advancing the adhesive-backed carrier tape to a pick station,
c. heating the thermal release adhesive material, and
d. removing the component from the thermal release adhesive material.

2. The method of claim 1 wherein the component is an IC chip.

3. The method of claim 1 wherein the carrier tape comprises a plurality of individual compartments and the component is placed in one of the plurality of individual compartments.

4. The method of claim 1 wherein the thermal release adhesive material is heated with a ceramic heating element.

5. The method of claim 1 wherein the thermal release adhesive material is heated using a heat source selected from the group consisting of lasers, arc lamps, heat lamps, and induction heaters.

6. The method of claim 1 wherein the thermal release adhesive material has essentially zero adhesion at a temperature above approximately 90 degrees C.

7. The method of claim 6 wherein the thermal release adhesive material is heated from room temperature to a temperature of at least 90 degrees C. in less than 500 ms.

8. The method of claim 1 wherein the thermal release material is heated by applying heat to the component.

9. The method of claim 7 wherein the thermal release adhesive material undergoes a change in adhesion of at least 0.5 N/20 mm.

10. A component carrier tape comprising an elongated flexible tape with a front side and a back side, with component site openings extending through said component carrier tape, said component site openings having an adhesive backing extending along the back side of the component carrier tape, the component carrier tape characterized in that the adhesive backing comprises a thermal release adhesive material.

11. The component carrier tape of claim 10 wherein the flexible tape has sprocket openings along an edge of the tape for engaging a sprocket wheel.

12. The component carrier tape of claim 11 wherein the adhesive backing is a continuous single strip of adhesive tape.

13. The component carrier tape of claim 12 wherein the continuous single strip of adhesive tape completely covers the said component site openings.

14. The component carrier tape of claim 10 wherein the thermal release adhesive material has essentially zero adhesion at a temperature above approximately 90 degrees C.

15. The component carrier tape of claim 14 wherein the thermal release adhesive material undergoes a change in adhesion of at least 0.5 N/20 mm when heated.

16. The component carrier tape of claim 10 wherein the adhesive backing is attached to the carrier tape by the thermal release adhesive material.

17. A component handling system comprising a vacuum pick head and a carrier tape conveying system for moving a carrier tape past the pick head so that components on the carrier tape can be picked from the carrier tape, the invention comprising a heating assembly located in the vicinity of the pick head for heating the carrier tape as it moves to and from the vicinity of the pick head.

18. The component handling system of claim 17 wherein the heating assembly comprises a heating device selected from the group consisting of ceramic heaters, arc lamps, tungsten halogen lamps, xenon lamps, lasers, and infra-red lamps.

19. The component handling system of claim 18 wherein the heating device produces a rise time from room temperature to above 90 degrees C. in less than 500 ms.

20. The component handling system of claim 19 wherein the sprocket wheels define a path for the carrier tape, and the heating assembly includes an anvil that is raised and lowered with respect to the path of the carrier tape.

21. The method of claim 3 wherein two or more components are placed in a single compartment.

22. The method of claim 21 wherein the two or more components are the same type.

23. The method of claim 21 wherein the two or more components are different types.

24. The method of claim 21 wherein the two or more components are simultaneously removed.

25. The method of claim 21 wherein the two or more components are serially removed.

26. The method of claim 25 wherein the two or more components are removed using a pick head, and the pick head is moved to remove the two or more components while the adhesive-backed carrier tape is stationary.
